(19) United States
(12) Patent Application Publication
(10) Pub. No.: US 2026/0279410 A1
(43) Pub. Date: Sep. 17, 2026

(54) MEMORY DEVICE AND METHOD OF FABRICATION

(71) Applicant: SK hynix Inc., Icheon-si (KR)

(72) Inventors: Sung Lae OH, Icheon-si (KR); Sang Hyun SUNG, Icheon-si (KR)

(21) Appl. No.: 19/276,791

(22) Filed: Jul. 22, 2025

(30) Foreign Application Priority Data
Mar. 13, 2025 (KR) 10-2025-0032669

(51) Int. Cl. G11C 5/06; H10B 41/10; H10B 41/27; H10B 43/10; H10B 43/27; H10W 90/00

(52) U.S. Cl. CPC G11C 5/063; H10B 41/10; H10B 41/27; H10B 43/10; H10B 43/27; H10W 90/792

(57) ABSTRACT

A memory device includes a stack including a plurality of electrode layers and a plurality of interlayer insulating layers that are vertically alternately stacked; a cell plug vertically penetrating the stack; a source plate disposed on the stack and connected to the cell plug; a contact vertically penetrating the stack and connected to one of the plurality of electrode layers; and a pass transistor disposed on the stack, and including a semiconductor pillar that is connected to the contact, a gate insulating layer that surrounds an outer wall of the semiconductor pillar and a gate electrode that surrounds an outer wall of the gate insulating layer.

### CROSS-REFERENCE TO RELATED APPLICATION

The present application claims priority under 35 U.S.C. §119(a) to Korean Patent Application No. 10-2025-0032669 filed in the Korean Intellectual Property Office on March 13, 2025, which is incorporated herein by reference in its entirety.

### BACKGROUND

### 1. Technical Field

Embodiments of the present disclosure relate to a memory device and a method of fabricating the same.

### 2. Related Art

Memory devices with two-dimensional or planar structures have been developed to be able to store more data within the same area by using fine patterning processes as compared to conventional devices. However, with increasingly narrow circuit line widths due to demands for high integration, interference between memory cells worsens, resulting in various limitations such as deterioration in performance. Of course, in addition to these structural limitations, there is also a problem because expensive equipment is required to pattern fine line widths, which inevitably increases fabricating costs.

Three-dimensional memory devices have been proposed as an alternative to overcome the limitations of two-dimensional memory devices. The three-dimensional memory devices have advantages in that larger capacity may be realized within the same area by increasing the number of stacks through stacking memory cells in a vertical direction, thereby providing high performance and excellent power efficiency.

In the three-dimensional memory devices, the degree of integration may be increased by increasing the number of electrode layers (word lines) to be stacked. However, as the number of stacked electrode layers increases, the number of pass transistors that transmit operating voltages to the electrode layers also increases, which may increase chip size.

### SUMMARY

Embodiments of the present disclosure are directed to providing a memory device capable of reducing chip size and a method of fabricating the same.

Objects of embodiments of the disclosure are not limited to those set forth herein, and other objects not mentioned here will be apparent to one of ordinary skill in the art from the following description.

In an embodiment, a memory device may include: a stack including a plurality of electrode layers and a plurality of interlayer insulating layers that are vertically alternately stacked; a cell plug vertically penetrating the stack; a source plate disposed on the stack and connected to the cell plug; a contact vertically penetrating the stack and connected to one of the plurality of electrode layers; and pass transistor disposed on the stack, and including a semiconductor pillar that is connected to the contact, a gate insulating layer that surrounds an outer wall of the semiconductor pillar and a gate electrode that surrounds an outer wall of the gate insulating layer.

In an embodiment, a memory device may include: a first semiconductor chip including a first bonding pad; and a second semiconductor chip disposed under the first semiconductor chip, and including a second bonding pad bonded to the first bonding pad. The first semiconductor chip may include: a stack disposed over the first bonding pad, and including a plurality of electrode layers and a plurality of interlayer insulating layers that are vertically alternately stacked; a cell plug vertically penetrating the stack; a contact vertically penetrating the stack and connected to one of the plurality of electrode layers; a source plate disposed on the stack and connected to the cell plug; and a pass transistor disposed on the stack, and including a semiconductor pillar that is connected to the contact, a gate insulating layer that surrounds an outer sidewall of the semiconductor pillar and a gate electrode that surrounds an outer sidewall of the gate insulating layer.

In an embodiment, a method of fabricating a memory device may include: forming, in a first surface of a substrate, a trench and a semiconductor pillar that protrudes from a plane common to a bottom surface of the trench; forming a gate insulating layer that surrounds a sidewall of the semiconductor pillar; forming, in the trench, a gate electrode that surrounds a sidewall of the gate insulating layer; forming a stack that includes a plurality of electrode layers and a plurality of interlayer insulating layers alternately stacked, a cell plug that penetrates the stack and extends to the substrate, and a contact that penetrates the stack and is connected to the semiconductor pillar; polishing a second surface of the substrate opposite to the first surface to expose the semiconductor pillar and the gate electrode; partially removing the substrate to expose a part of the stack and the cell plug; and forming a source plate on the exposed part of the stack.

According to the embodiments of the present disclosure, it is possible to provide a memory device and a method of fabricating the same, capable of reducing chip size by reducing an area consumed by the disposition of pass transistors.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a cross-sectional view illustrating a section of a memory device according to an embodiment of the present disclosure.

FIG. 2 is a plan view illustrating pass transistors, a first substrate, a source plate and an isolation pattern of FIG. 1.

FIG. 3 is a cross-sectional view illustrating a section of a memory device according to an embodiment of the present disclosure.

FIG. 4 is a flowchart showing a method of fabricating a memory device according to an embodiment of the present disclosure.

FIG. 5 to FIG. 16 are views illustrating a method of fabricating a memory device according to embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element in between.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

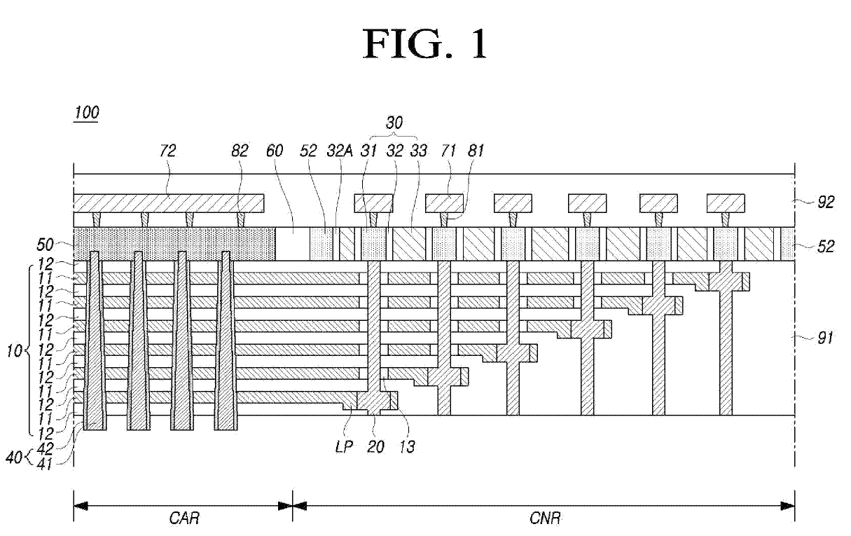

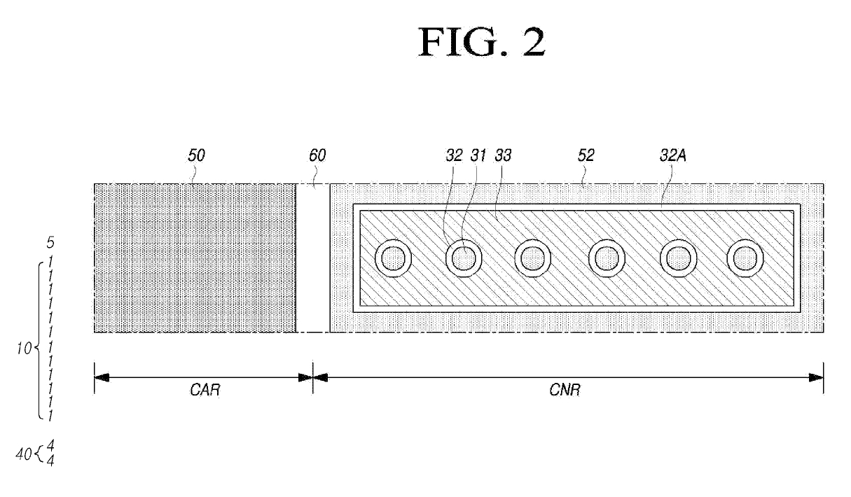

FIG. 1 is a cross-sectional view illustrating a section of a memory device according to an embodiment of the present disclosure, and FIG. 2 is a plan view illustrating pass transistors, a first substrate, a source plate and an isolation pattern of FIG. 1.

Referring to FIG. 1, a memory device 100 according to an embodiment of the present disclosure may include a stack 10, a contact 20, a pass transistor 30, a cell plug 40, and a source plate 50.

The stack 10 may include a plurality of electrode layers 11 and a plurality of interlayer insulating layers 12 that are vertically alternately stacked. The memory device 100 may include a cell region CAR and a connection region CNR. The stack 10 may be disposed in the cell region CAR and the connection region CNR.

The electrode layers 11 may include at least one selected among doped semiconductor, metal, conductive metal nitride or transition metal. The doped semiconductor may include doped silicon. The metal may include at least one selected among tungsten, copper or aluminum. The conductive metal nitride may include at least one selected among titanium nitride or tantalum nitride. The transition metal may include at least one selected among titanium or tantalum. The interlayer insulating layers 12 may include silicon oxide.

The electrode layers 11 may form row lines. The row lines may include at least one source select line, a plurality of word lines, and a plurality of drain select lines. At least one from the top among the electrode layers 11 may constitute a source select line. At least one from the bottom among the electrode layers 11 may constitute a drain select line. Electrode layers 11 between the source select line and the drain select line may constitute word lines.

A stairway structure may be formed by the electrode layers 11 that extend by different lengths in the connection region CNR. A pad area LP of an overlying electrode layer 11 may protrude more than an underlying electrode layer 11 in a horizontal direction. The pad area LP may be thicker than other parts of the electrode layer 11. Pad areas LP of the electrode layers 11 may be disposed in a stairway shape.

A first insulating layer 91 may be disposed under the stack 10 to cover the stack 10. The first insulating layer 91 may include oxide or/and nitride. A contact 20 may vertically penetrate the first insulating layer 91 and the stack 10, and may be connected to a corresponding electrode layer 11. The contact 20 may penetrate the pad area LP of a corresponding electrode layer 11, and may be connected to the pad area LP of the corresponding electrode layer 11. An insulating pattern 13 may be disposed between the contact 20 and electrode layers 11, other than the corresponding electrode layer 11. The insulating pattern 13 may electrically isolate the contact 20 and the other electrode layers 11, other than the corresponding electrode layer 11. The insulating pattern 13 may be disposed in the stack direction between two neighboring interlayer insulating layers 12 among the plurality of interlayer insulating layers 12. The insulating pattern 13 may be formed of an insulating material that has an etching selectivity different from that of the interlayer insulating layers 12. For example, the interlayer insulating layers 12 may be formed of oxide, and the insulating pattern 13 may be formed of nitride.

The pass transistor 30 may be disposed on the stack 10 in the connection region CNR. A plurality of pass transistors 30 may be disposed on the stack 10. Each pass transistor 30 may include a semiconductor pillar 31, a gate insulating layer 32, and a gate electrode 33.

The semiconductor pillar 31 may vertically extend from the contact 20. The semiconductor pillar 31 may be formed of a semiconductor material. The semiconductor material may include monocrystalline silicon.

The channel of the pass transistor 30 may be formed through the semiconductor pillar 31. The channel of the pass transistor 30 may extend in the vertical direction, which is the extending direction of the semiconductor pillar 31.

The semiconductor pillar 31 may be connected to the contact 20. The semiconductor pillar 31 may contact the contact 20. The semiconductor pillar 31 may be connected to a corresponding electrode layer 11 through the contact 20.

Referring to FIG. 1 and FIG. 2, the gate insulating layer 32 may surround an outer wall of the semiconductor pillar 31. The gate insulating layer 32 may have a straw or cylinder shell shape.

The gate electrode 33 may surround an outer wall of the gate insulating layer 32. The gate electrode 33 may surround the outer walls of the gate insulating layers 32 of the plurality of pass transistors 30. The gate electrode 33 may be shared by the plurality of pass transistors 30. The height of the gate electrode 33 may be substantially the same as the height of the semiconductor pillar 31.

A first substrate 52 may surround a sidewall of the gate electrode 33 facing away from the pass transistors 30. The first substrate 52 may be formed of the same material as the semiconductor pillar 31. For example, the first substrate 52 may be formed of monocrystalline silicon.

An insulating spacer 32A may be disposed between the gate electrode 33 and the first substrate 52. The insulating spacer 32A may be formed in the same process as the gate insulating layer 32. The insulating spacer 32A may be formed of the same material as the gate insulating layer 32.

The pass transistor 30 may transmit an operating voltage to the electrode layer 11. Operating voltages may include a program voltage (Vpgm), an unselected read voltage (Vread), a read voltage (Vrd), a pass voltage (Vpass) and a verify voltage (Vfy). The unselected read voltage (Vread) is a voltage that is provided to an unselected word line during a read operation. The read voltage (Vrd) is a voltage that is provided to a selected word line during a read operation. The program voltage (Vpgm), the pass voltage (Vpass) or the unselected read voltage (Vread) corresponds to a high voltage. The pass transistor 30 is a high-voltage transistor, and the channel of the pass transistor 30 requires a length longer than the channel of a low-voltage transistor to withstand a high voltage.

Unlike the present disclosure, when the channel of a pass transistor is planarly disposed, the planar area of the pass transistor must be comparatively larger to provide a pass transistor with a longer channel length, which may increase the size of a memory device.

According to the present disclosure, because the channel of the pass transistor 30 is vertically disposed in the extending direction of the semiconductor pillar 31, the height of the semiconductor pillar 31 may be increased to configure the pass transistor 30 with a longer channel length. Therefore, the pass transistor 30 with a longer channel length may be disposed within a smaller area, and area consumption due to the presence of the pass transistor 30 may be reduced, thereby reducing the size of the memory device 100 as compared to comparative devices.

The cell plug 40 may vertically penetrate the first insulating layer 91 and the stack 10 in the cell region CAR. The cell plug 40 may include a cell channel layer 41 and a cell gate insulating layer 42.

The cell channel layer 41 may be formed of a semiconductor material. For example, the cell channel layer 41 may include silicon. The upper end of the cell channel layer 41 may protrude out of the upper surface of the stack 10.

The cell gate insulating layer 42 may have a straw or cylinder shell shape that surrounds an outer wall of the cell channel layer 41. The cell gate insulating layer 42 may include a tunnel insulating layer, a charge storage layer and a blocking layer that are sequentially stacked from the outer sidewall of the cell channel layer 41. In some embodiments, the cell gate insulating layer 42 may have an ONO (oxide-nitride-oxide) stack structure in which an oxide layer, a nitride layer and an oxide layer are sequentially stacked. The upper end of the cell channel layer 41 protruding out of the upper surface of the stack 10, however, may not be covered with the cell gate insulating layer 42.

Memory cells may be formed in areas where word lines surround the cell plug 40. A source select transistor may be formed in an area where a source select line surrounds the cell plug 40. A drain select transistor may be formed in an area where a drain select line surrounds the cell plug 40. A source select transistor, a plurality of memory cells and a drain select transistor that are disposed along one cell plug 40 may form one cell string.

In the cell region CAR, a plurality of cell plugs 40 may vertically penetrate the stack 10. A plurality of cell strings corresponding to the plurality of cell plugs 40 may be defined. The plurality of cell strings may form a memory cell array.

The source plate 50 may be disposed on the stack 10 in the cell region CAR. The source plate 50 may be connected to the cell plug 40. The source plate 50 may surround the upper end of the cell channel layer 41 that protrudes out of the stack 10. The source plate 50 may be connected to the cell channel layer 41.

The source plate 50 may be disposed at substantially the same height level as the gate electrode 33. The source plate 50 may have a thickness that is the same as the thickness of the semiconductor pillar 31. The source plate 50 may be formed of a semiconductor material. The source plate 50 may be formed of a semiconductor material that has a different crystal structure from the semiconductor material used in the semiconductor pillar 31. The semiconductor pillar 31 may be formed of monocrystalline silicon, and the source plate 50 may be formed of polycrystalline silicon.

An isolation pattern 60 may be disposed between the source plate 50 and the first substrate 52. The source plate 50 and the first substrate 52 may be isolated by the isolation pattern 60. The isolation pattern 60 may be formed of an insulating material. The insulating material may include oxide.

A global row line 71 (not illustrated in FIG. 2) may be disposed over the pass transistor 30. The global row line 71 may be connected to the semiconductor pillar 31 of the pass transistor 30 through a first via 81 (not illustrated in FIG. 2). The global row line 71 may be connected to a voltage generator (not illustrated) and may transmit an operating voltage provided from the voltage generator to the pass transistor 30.

A source line 72 may be disposed over the source plate 50. The source line 72 is connected to the source plate 50 through a second via 82 (not illustrated in FIG. 2). The source line 72 may transmit a source voltage to the source plate 50. The source line 72 may be disposed at the same height level as the global row line 71. The source line 72 may be formed through the same process as the global row line 71. The source line 72 may be formed of the same material as a material that forms the global row line 71, and may have the same thickness as the thickness of the global row line 71.

A second insulating layer 92 (not illustrated in FIG. 2) may be disposed on the pass transistor 30, the source plate 50, the first substrate 52 and the isolation pattern 60. The second insulating layer 92 may cover the global row line 71, the source line 72 and the first and second vias 81 and 82. The second insulating layer 92 may include oxide or/and nitride.

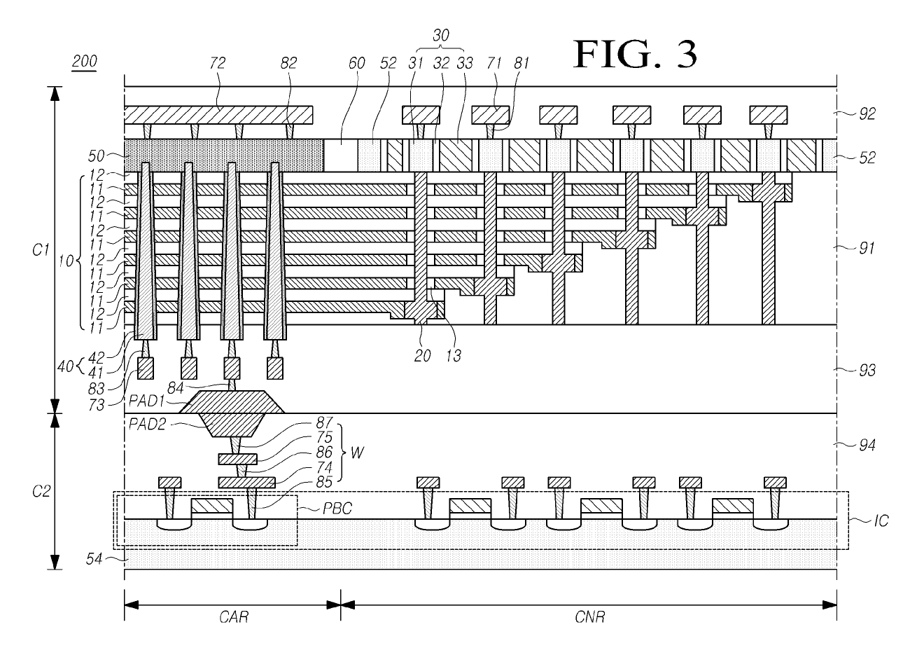

FIG. 3 is a cross-sectional view illustrating a section of a memory device according to an embodiment of the present disclosure.

Referring to FIG. 3, a memory device 200 according to an embodiment of the present disclosure may include a first semiconductor chip C1 and a second semiconductor chip C2.

The first semiconductor chip C1 may be disposed on the second semiconductor chip C2. The lower surface of the first semiconductor chip C1 and the upper surface of the second semiconductor chip C2 may be bonded to each other.

The first semiconductor chip C1 may include a stack 10, a contact 20, a pass transistor 30, a source plate 50, a first substrate 52, a global row line 71, a source line 72, first and second vias 81 and 82, and first and second insulating layers 91 and 92. In addition, the first semiconductor chip C1 may further include a bit line (BL) 73, third and fourth vias 83 and 84, a third insulating layer 93, and a first bonding pad PAD1.

Because the stack 10, the contact 20, the pass transistor 30, the source plate 50, the first substrate 52, the global row line 71, the source line 72, the first and second vias 81 and 82 and the first and second insulating layers 91 and 92 have been described above with reference to FIG. 1 and FIG. 2, duplicate descriptions for the same components will be omitted.

The bit line (BL) 73 may be disposed below the stack 10, and may be connected to a cell plug 40 through the third via 83. The third insulating layer 93 may be disposed under the first insulating layer 91, and may cover the lower end of the cell plug 40, which extends through the stack 10, and the bit line (BL) 73.

The first bonding pad PAD1 may be disposed below the bit line (BL) 73, and may be connected to the bit line (BL) 73 through the fourth via 84. The upper surface and side surfaces of the first bonding pad PAD1 may be covered with the third insulating layer 93, and the lower surface of the first bonding pad PAD1 may be exposed at the lower surface of the third insulating layer 93. The lower surface of the third insulating layer 93 and the lower surface of the first bonding pad PAD1 may form the lower surface of the first semiconductor chip C1.

The second semiconductor chip C2 may include a second substrate 54, a logic circuit IC, a fourth insulating layer 94, a wiring structure W, and a second bonding pad PAD2.

The second substrate 54 may include a semiconductor material. The semiconductor material may include silicon. The logic circuit IC may be disposed on the second substrate 54. The logic circuit IC may include a page buffer circuit PBC. In addition, the logic circuit IC may include a control logic and a voltage generator, but embodiments are not limited thereto.

The wiring structure W may be connected to the logic circuit IC. The wiring structure W may include wirings 74 and 75 that are disposed at different height levels and a plurality of vias 85, 86 and 87. The fourth insulating layer 94 may be disposed on the second substrate 54, and may cover the logic circuit IC and the wiring structure W.

The second bonding pad PAD2 may be disposed on the wiring structure W, and may be connected to the logic circuit IC through the wiring structure W. As illustrated in FIG. 3, the second bonding pad PAD2 may be connected to the page buffer circuit PBC through the wiring structure W. The lower surface and side surfaces of the second bonding pad PAD2 may be covered with the fourth insulating layer 94, and the upper surface of the second bonding pad PAD2 may be exposed at the upper surface of the fourth insulating layer 94. The upper surface of the fourth insulating layer 94 and the upper surface of the second bonding pad PAD2 may form the upper surface of the second semiconductor chip C2. The first bonding pad PAD1 may be bonded to the second bonding pad PAD2, and the third insulating layer 93 may be bonded onto the fourth insulating layer 94.

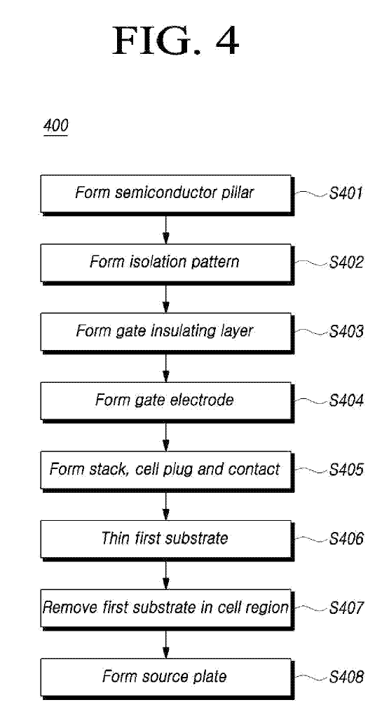

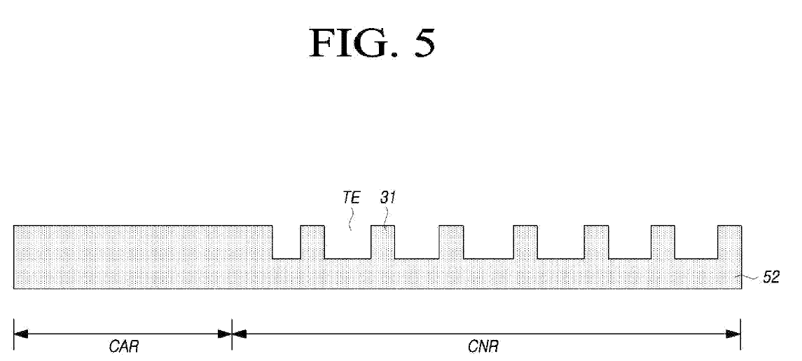

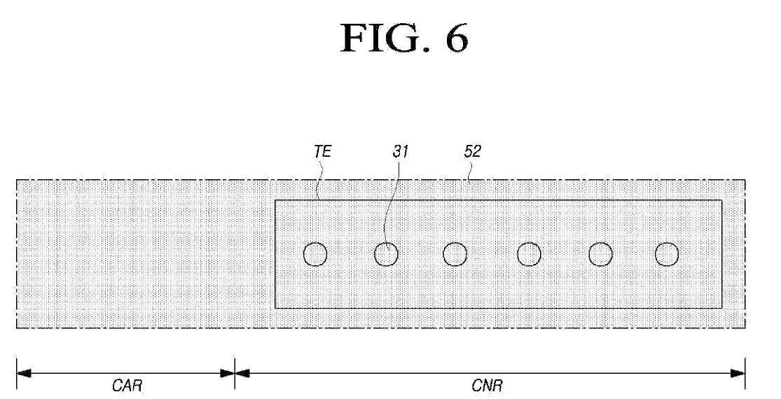

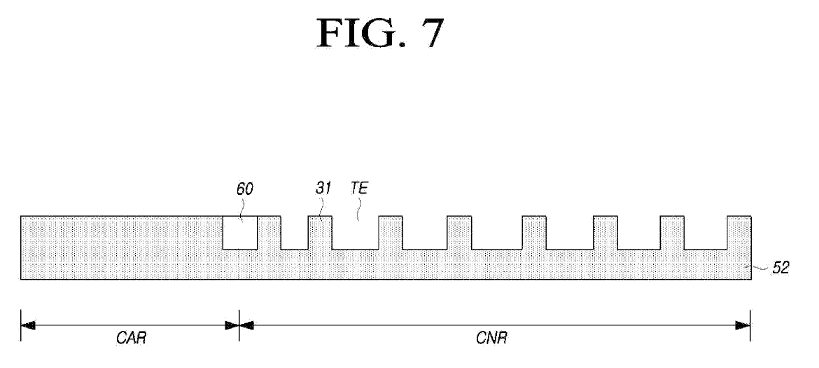

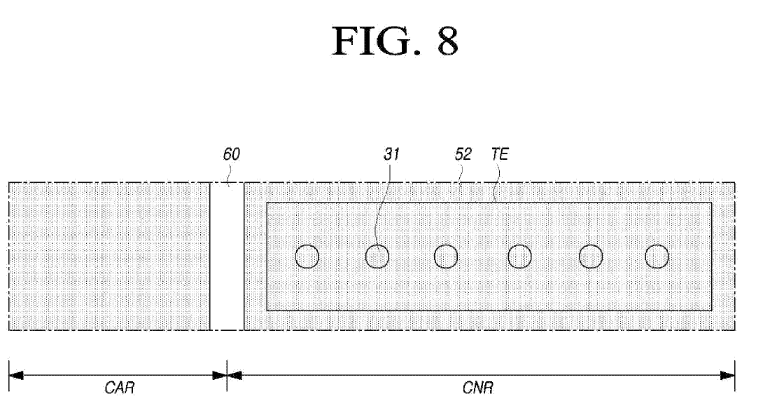

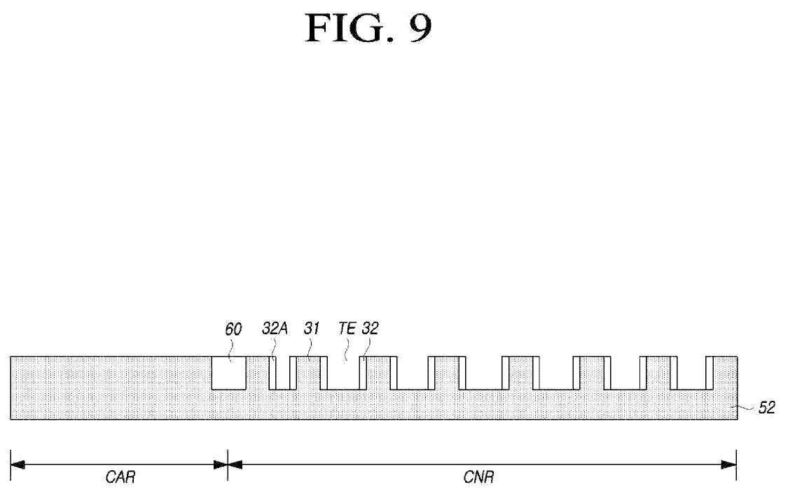

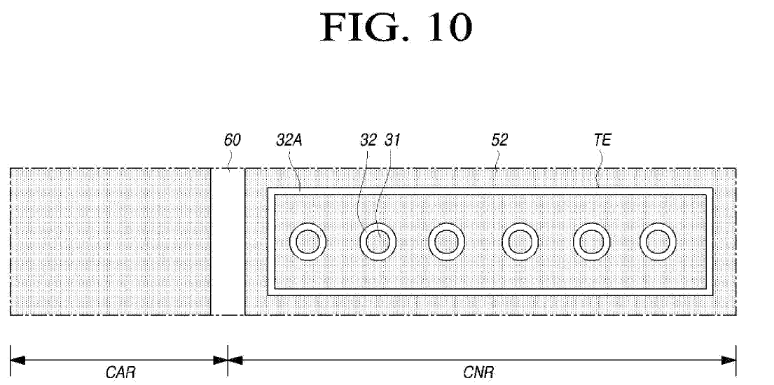

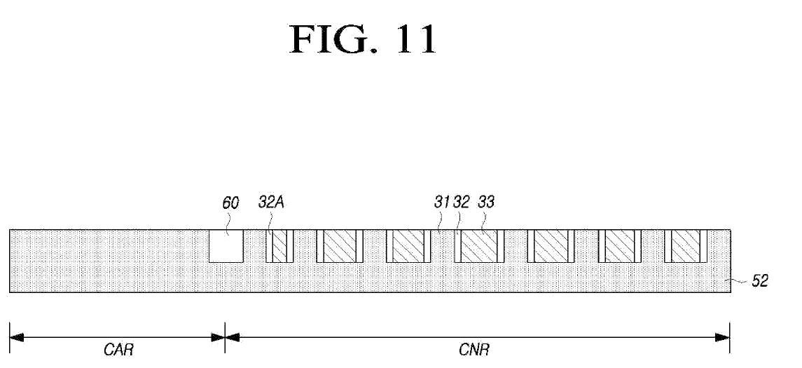

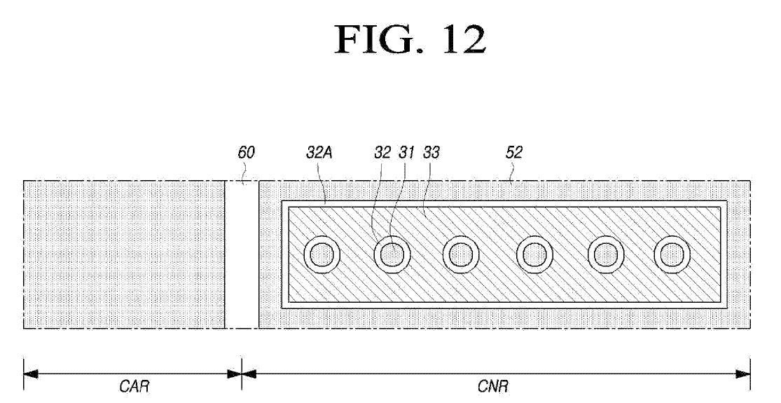

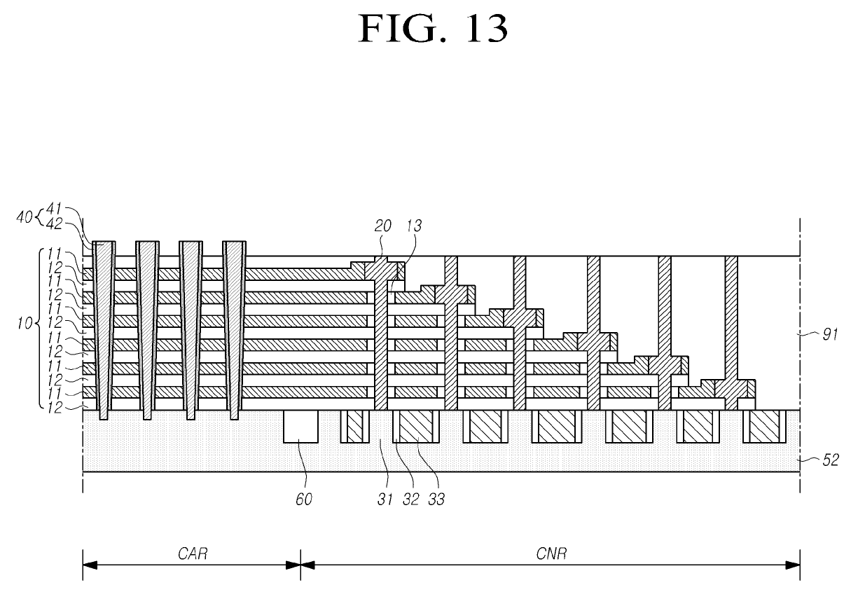

FIG. 4 is a flowchart showing a method of fabricating a memory device according to an embodiment of the present disclosure, and FIG. 5 to FIG. 16 are views illustrating the method of fabricating a memory device according to embodiments of the present disclosure. FIG. 5, FIG. 7, FIG. 9, FIG. 11 an FIG. 13 to FIG. 16 are cross-sectional views, FIG. 6 is a plan view of FIG. 5, FIG. 8 is a plan view of FIG. 7, FIG. 10 is a plan view of FIG. 9, and FIG. 12 is a plan view of FIG. 11.

Referring to FIG. 4, a method 400 of fabricating a memory device according to an embodiment of the present disclosure may include a step of forming a semiconductor pillar in a first substrate (S401), a step of forming an isolation pattern (S402), a step of forming a gate insulating layer (S403), a step of forming a gate electrode (S404), a step of forming a stack, a cell plug and a contact (S405), a step of thinning the first substrate (S406), a step of removing the first substrate in a cell region (S407), and a step of forming a source plate (S408).

Referring to FIG. 5 and FIG. 6, a semiconductor pillar 31 may be formed in a first substrate 52.

The first substrate 52 may include a semiconductor material. The semiconductor material may include monocrystalline silicon.

In a connection region CNR, a trench TE may be formed in the first surface (upper surface) of the first substrate 52. The semiconductor pillar 31 may vertically protrude from a plane common to the bottom surface of the trench TE. The semiconductor pillar 31 may be disposed inside the trench TE. A plurality of semiconductor pillars 31 may be formed inside the trench TE.

Referring to FIG. 7 and FIG. 8, an isolation pattern 60 may be formed.

The isolation pattern 60 may extend from a first surface of the first substrate 52 into the interior of the first substrate 52. The isolation pattern 60 may be disposed in an area between the cell region CAR and the connection region CNR. The isolation pattern 60 may be disposed to represent a boundary between the cell region CAR and the connection region CNR. The isolation pattern 60 may include an insulating material. The insulating material may include oxide.

A process of forming the isolation pattern 60 may include forming a groove in the first surface of the first substrate 52, forming an insulating material to fill the groove, and removing the insulating material formed outside the groove.

Referring to FIG. 9 and FIG. 10, a gate insulating layer 32 may be formed.

The gate insulating layer 32 may surround an outer sidewall of the semiconductor pillar 31. A process of forming the gate insulating layer 32 may include forming an insulating layer that covers the first substrate 52 and the semiconductor pillars 31, and removing the insulating layer that is formed on the first surface of the first substrate 52, and removing the insulating layer to expose the top surfaces of the semiconductor pillars 31 and the bottom surface of the trench. An etch-back process may be used as the process of removing the insulating layer that is formed on the first surface of the first substrate 52, the top surfaces of semiconductor pillars 31. and the bottom surface of the trench.

In the process of forming the gate insulating layer 32, an insulating spacer 32A may be formed on the sidewall of the trench TE. The insulating spacer 32A may cover the sidewall of the trench TE.

Referring to FIG. 11 and FIG. 12, a gate electrode 33 may be formed.

The gate electrode 33 may surround the outer wall of the gate insulating layer 32. The gate electrode 33 may fill the trench TE.

A process of forming the gate electrode 33 may include filling the trench TE with an electrode material, and then removing the electrode material that is formed outside the trench TE.

Referring to FIG. 13, a stack 10, a first insulating layer 91, a contact 20 and a cell plug 40 may be formed.

The stack 10 may be disposed on the first substrate 52, the semiconductor pillar 31, the gate insulating layer 32, the gate electrode 33, the insulating spacer 32A and the isolation pattern 60. The stack 10 may include a plurality of electrode layers 11 and a plurality of interlayer insulating layers 12 that are vertically and alternately stacked.

The first insulating layer 91 may cover the stack 10. The contact 20 may vertically penetrate the first insulating layer 91 and the stack 10 in the connection region CNR, and may be connected to the semiconductor pillar 31. The contact 20 may be connected to one corresponding electrode layer 11. An insulating pattern 13 may be disposed between other electrode layers 11, other than the corresponding one electrode layer 11, and the contact 20. The insulating pattern 13 may isolate the contact 20 from the other electrode layers 11 other than the corresponding electrode layer 11.

The cell plug 40 may vertically penetrate the first insulating layer 91 and the stack 10 in the cell region CAR, and may extend into the first substrate 52. The cell plug 40 may include a cell channel layer 41 and a cell gate insulating layer 42. The lower end of the cell channel layer 41 may penetrate the first surface of the first substrate 52, and may extend into the interior of the first substrate 52.

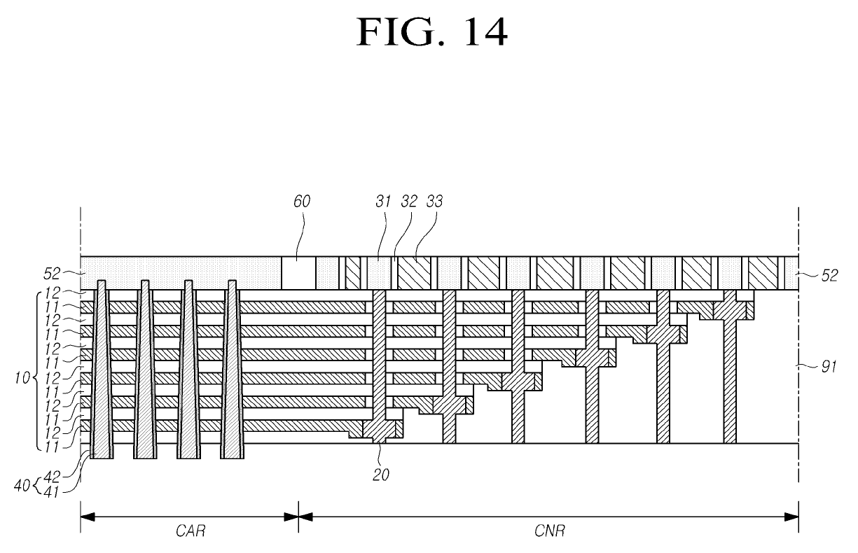

Referring to FIG. 14, the structure of FIG. 13 may be turned upside down, and the first substrate 52 may be thinned such that the semiconductor pillar 31, the gate insulating layer 32, the gate electrode 33 and the isolation pattern 60 are exposed.

In the thinning process, a second surface of the first substrate 52, which is opposite to the first surface, may be polished. In addition, the first substrate 52 of the cell region CAR and the first substrate 52 of the connection region CNR may be isolated from each other with the isolation pattern 60 interposed therebetween. A chemical mechanical polishing process may be used as the thinning process.

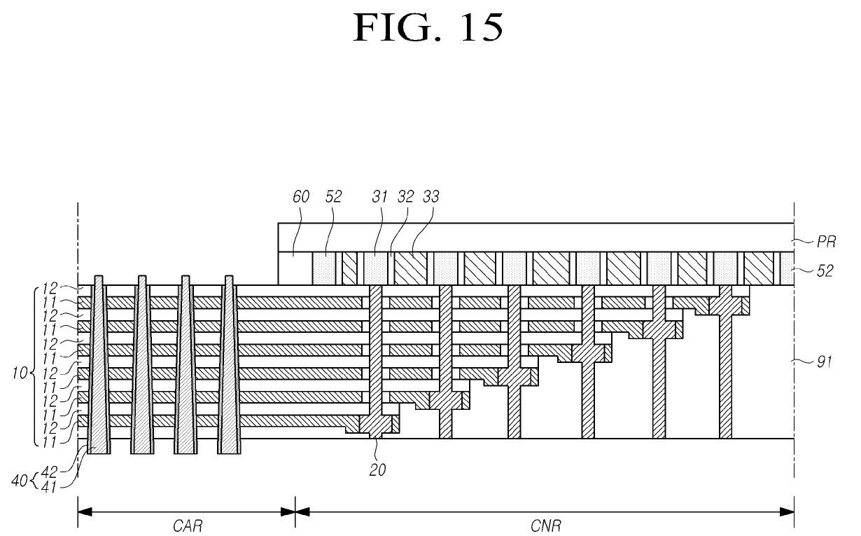

Referring to FIG. 15, the first substrate 52 in the cell region CAR may be removed.

When the first substrate 52 in the cell region CAR is removed, the stack 10 and the upper end of the cell channel layer 41 may be exposed.

A process of removing the first substrate 52 in the cell region CAR may include forming a mask pattern PR that covers the first substrate 52, the semiconductor pillar 31, the gate insulating layer 32 and the gate electrode 33 in the connection region CNR, exposing the first substrate 52 in the cell region CAR, and removing the first substrate 52 in the cell region CAR using the mask pattern PR as an etch mask.

The mask pattern PR may be formed using photoresist. The mask pattern PR that remains after removing the first substrate 52 may be removed by a strip process.

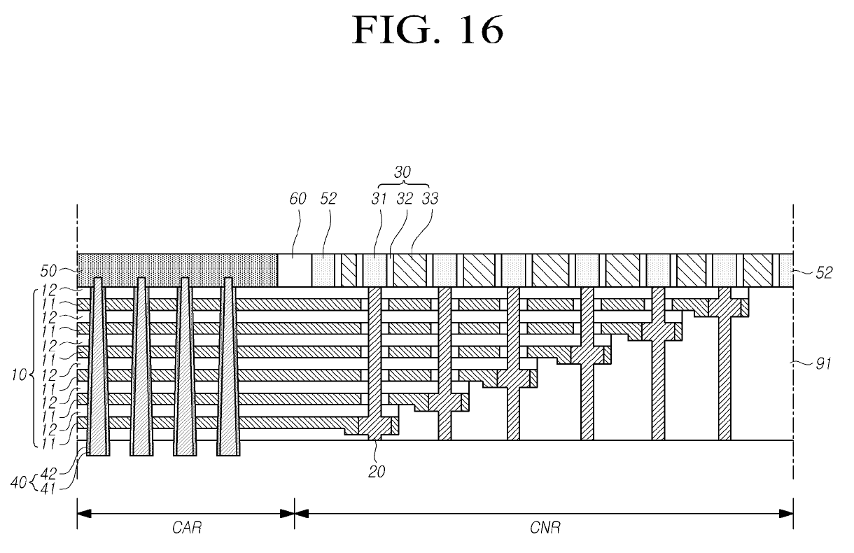

Referring to FIG. 16, a source plate 50 may be formed.

The source plate 50 may be formed on the stack 10 in the cell region CAR. The source plate 50 may cover the upper end of the cell channel layer 41.

The source plate 50 may include a semiconductor material. The semiconductor material that forms the source plate 50 may have a crystal structure that is different from that of the semiconductor material used in the semiconductor pillar 31 and the first substrate 52. For example, the source plate 50 may be formed of polycrystalline silicon, and the semiconductor pillar 31 and the first substrate 52 may be formed of monocrystalline silicon.

A process of forming the source plate 50 may include forming a semiconductor material on the stack 10 and over the first substrate 52, and polishing the semiconductor material such that the semiconductor pillar 31, the gate insulating layer 32, the gate electrode 33 and the isolation pattern 60 are exposed. A chemical mechanical polishing (CMP) process may be used as a polishing process.

The order of process steps of fabricating a memory device according to the present disclosure is not limited to the order illustrated in FIG. 4 to FIG. 16. The order of process steps may be flexibly changed.

According to embodiments of the present disclosure, the pass transistor 30 having the semiconductor pillar 31 that vertically extends on the stack 10 may be formed so that the pass transistor 30 with a longer channel length is disposed within a small area, whereby it is possible to reduce area consumption by the pass transistor 30 and reduce the size of a memory device. Because the pass transistor 30 is connected to a corresponding electrode layer 11 through the contact 20 that penetrates the stack 10, the length of the signal transmission path between the pass transistor 30 and the electrode layer 11 may be configured to be shorter, thereby reducing signal delay.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A memory device comprising:
a stack including a plurality of electrode layers and a plurality of interlayer insulating layers that are vertically alternately stacked;
a cell plug vertically penetrating the stack;
a source plate disposed on the stack and connected to the cell plug;
a contact vertically penetrating the stack and connected to one of the plurality of electrode layers; and
a pass transistor disposed on the stack, and including a semiconductor pillar that is connected to the contact, a gate insulating layer that surrounds an outer wall of the semiconductor pillar and a gate electrode that surrounds an outer wall of the gate insulating layer.

2. The memory device according to claim 1, wherein the gate electrode is disposed at the same height level as the source plate.

3. The memory device according to claim 1, wherein the semiconductor pillar has the same thickness as the source plate.

4. The memory device according to claim 1, wherein the source plate includes a semiconductor material that has a crystal structure different from a semiconductor material forming the semiconductor pillar.

5. The memory device according to claim 1, wherein the source plate includes polycrystalline silicon, and the semiconductor pillar includes monocrystalline silicon.

6. The memory device according to claim 1, further comprising
a global row line disposed over the pass transistor and connected to the semiconductor pillar.

7. The memory device according to claim 6, further comprising
a source line disposed over the source plate and connected to the source plate,
wherein the source line is disposed at the same height level as the global row line.

8. The memory device according to claim 1, further comprising
a substrate surrounding an outer wall of the gate electrode.

9. The memory device according to claim 8, further comprising
an isolation pattern disposed between the source plate and the substrate.

10. A memory device comprising:
a first semiconductor chip including a first bonding pad; and
a second semiconductor chip disposed under the first semiconductor chip, and including a second bonding pad bonded to the first bonding pad,
the first semiconductor chip comprising:
a stack disposed over the first bonding pad, and including a plurality of electrode layers and a plurality of interlayer insulating layers that are vertically alternately stacked;
a cell plug vertically penetrating the stack;
a contact vertically penetrating the stack and connected to one of the plurality of electrode layers;
a source plate disposed on the stack and connected to the cell plug; and
a pass transistor disposed on the stack, and including a semiconductor pillar that is connected to the contact, a gate insulating layer that surrounds an outer sidewall of the semiconductor pillar and a gate electrode that surrounds an outer sidewall of the gate insulating layer.

11. The memory device according to claim 10, wherein the gate electrode is disposed at the same height level as the source plate.

12. The memory device according to claim 10, wherein the source plate includes a semiconductor material that has a crystal structure different from a semiconductor material forming the semiconductor pillar.

13. The memory device according to claim 10, wherein the source plate includes polycrystalline silicon, and the semiconductor pillar includes monocrystalline silicon.

14. The memory device according to claim 10, wherein
the cell plug is connected to the first bonding pad, and
the second semiconductor chip further includes a page buffer that is connected to the second bonding pad.

15. The memory device according to claim 10, wherein the first semiconductor chip further includes a global row line that is disposed over the pass transistor and is connected to the semiconductor pillar.

16. The memory device according to claim 15, wherein
the first semiconductor chip further includes a source line that is disposed over the source plate, and
the source line is disposed at the same height level as the global row line.

17. A method of fabricating a memory device, comprising:
forming, in a first surface of a substrate, a trench and a semiconductor pillar that protrudes from a plane common to a bottom surface of the trench;
forming a gate insulating layer that surrounds a sidewall of the semiconductor pillar;
forming, in the trench, a gate electrode that surrounds a sidewall of the gate insulating layer;
forming a stack that includes a plurality of electrode layers and a plurality of interlayer insulating layers alternately stacked, a cell plug that penetrates the stack and extends to the substrate, and a contact that penetrates the stack and is connected to the semiconductor pillar;
polishing a second surface of the substrate opposite to the first surface to expose the semiconductor pillar and the gate electrode;
partially removing the substrate to expose a part of the stack and the cell plug; and
forming a source plate on the exposed part of the stack.

18. The method according to claim 17, wherein the forming a source plate comprises:
forming a semiconductor material; and
polishing the semiconductor material such that the semiconductor pillar and the gate electrode are exposed.

19. The method according to claim 18, wherein the substrate includes monocrystalline silicon, and the semiconductor material includes polycrystalline silicon.
